(19) United States
(12) Patent Application Publication
(10) Pub. No.: US 2020/0105636 A1
(43) Pub. Date: Apr. 2, 2020

(54) CHIP PACKAGE STRUCTURE HAVING FUNCTION OF PREVENTING ADHESIVE FROM OVERFLOWING

(71) Applicant: LINGSEN PRECISION INDUSTRIES, LTD., Taichung City (TW)

(72) Inventors: Wei-Jen CHEN, TAICHUNG CITY (TW); Ming-Te TU, TAICHUNG CITY (TW)

(21) Appl. No.: 16/194,316

(22) Filed: Nov. 17, 2018

(30) Foreign Application Priority Data
Oct. 2, 2018 (TW) 107213366

(51) Int. Cl. H01L 23/31; H01L 23/495

(52) U.S. Cl. CPC H01L 23/3114; H01L 23/3128; H01L 23/49517

(57) ABSTRACT

A chip package structure includes a carrier board and a chip. The carrier board has a substrate, a plurality of first conductive pads mounted on an upper surface of the substrate and arranged around a concavity of the substrate, and a solder mask applied to the substrate and provided with a plurality of openings each exposing a portion of one respective first conductive pad. The chip is received in the concavity and attached to the carrier board through a bonding adhesive and provided with a plurality of second conductive pads electrically connected to the first conductive pads of the carrier board through a plurality of wires. By means of the concavity, an overflow of the bonding adhesive is avoided, and the overall package size is reduced.

### BACKGROUND OF THE INVENTION

### 1. Field of the Invention

The present invention relates to package technology, and more particularly to a chip package structure, which has an adhesive-overflowing prevention structure to prevent an overflow of a bonding adhesive during installation of a chip.

### 2. Description of the Related Art

As shown in FIG. 1, the conventional chip package structure is manufactured in a way that a chip 2 is attached to a carrier board 1 by using a bonding adhesive 3, and then a plurality of metal wires 4 are used to connect the chip 2 and the carrier board 1 together, and finally a package glue 5 (for example, epoxy resin) is applied to cover the chip 2.

When the chip 2 is bonded to the carrier board 1, the bonding adhesive 3 may be pressed to overflow on the surface of the carrier board 1, such that a dam is built around the chip 2 by using a solder mask 6 or higher viscosity glue to prevent the bonding adhesive 3 from contacting the bonding pads. However, the solder mask 6 has a limited thickness so as to cause a glue overflowing problem; and further, it is difficult to apply the higher viscosity glue to the carrier board 1 due to the small package size. As a result, the conventional chip package structure still has drawbacks and therefore needs improvements.

### SUMMARY OF THE INVENTION

It is a primary objective of the present invention to provide a chip package structure, which solves the problem of an overflow of a bonding adhesive and reduces the size of the chip package structure.

To attain the above objective, the present invention provides a carrier board, a chip, and a package glue. The carrier board includes a substrate having an upper surface and a concavity formed on the upper surface, a plurality of first conductive pads mounted on the upper surface of the substrate and arranged around the concavity of the substrate, and a solder mask applied to the substrate and having a plurality of openings respectively exposing portions of the first conductive pads. The chip is received in the concavity of the substrate and attached to the carrier board by using a bonding adhesive, and furthermore, the chip has a plurality of second conductive pads electrically connected to the first conductive pads of the carrier board through a plurality of wires. The package glue is applied to the carrier board for covering the first conductive pads of the carrier board, the chip, and the wires.

When pressed by the chip, the bonding adhesive flows in the concavity without overflowing to the first conductive pads. In this way, the concavity can prevent the bonding adhesive from damage to the bonding area, thereby reducing the thickness of the solder mask and decreasing the altitude of the chip to minimize package size.

Other advantages and features of the present invention will be fully understood by reference to the following specification in conjunction with the accompanying drawings, in which like reference signs denote like components of structure.

### BRIEF DESCRIPTION OF THE DRAWINGS

FIG. 1 is a schematic drawing of a chip package structure according to a prior art.

FIG. 2 is a schematic drawing of a chip package structure according to the present invention.

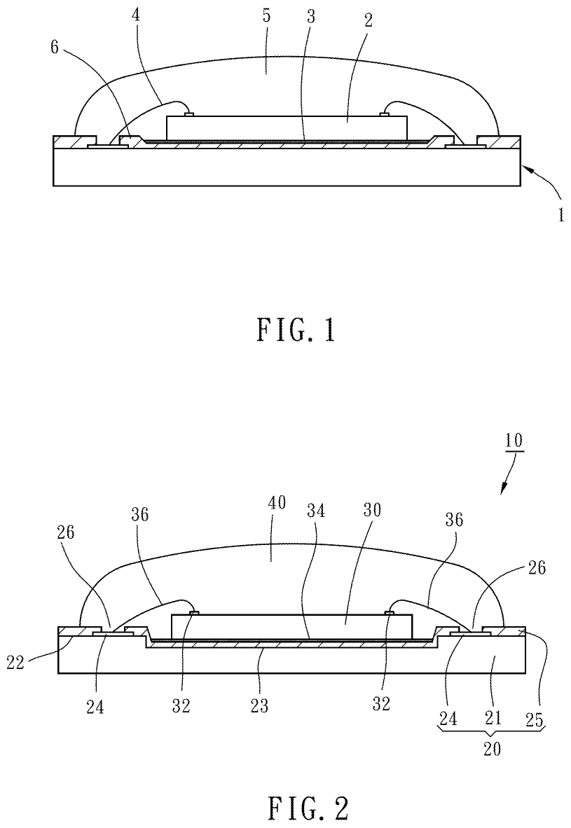

### DETAILED DESCRIPTION OF THE INVENTION

Referring to FIG. 2, a chip package structure 10 of the present invention includes a carrier board 20, a chip 30, and a package glue 40.

The carrier board 20 has a substrate 21, an unlimited number of first conductive pads 24, and a solder mask 25. The substrate 21 is provided with an upper surface 22 and a concavity 23 formed on the upper surface 22 and having a depth greater than 0.1 mm. The first conductive pads 24 are mounted on the upper surface 22 of the substrate 21 and arranged around the concavity 23 of the substrate 21. The solder mask 25 is applied to the substrate 21 and provided with a plurality of openings 26, wherein each of the openings 26 exposes a portion of one of the first conductive pads 24. Further, the substrate 21 in the present embodiment may, but unlimited to, be a bismaleimide-triazine (usually referred to as “BT”) substrate, a glass fiber substrate (usually referred to as “FR4”), or a direct bonded copper (usually referred to as “DBC”) substrate.

The chip 30 is received in the concavity 23 and attached to the carrier board 20 by using a bonding adhesive 34 and has an area smaller than an area of the concavity 23. Further, the chip 30 has an unlimited number of second conductive pads 32 each connected to the respective first conductive pad 24 of the carrier board 20 by using a wire 36.

The package glue 40 is applied to the carrier board 20 for covering the first conductive pads 24, and chip 30 and the wires 36.

By means of aforesaid design, the carrier board 20 has sufficient space to allow the bonding adhesive 34 to spread in the concavity 23 when the bonding adhesive 34 is pressed by the chip 30 during the installation of chip 30, such that the concavity 23 is effective in preventing the bonding adhesive 34 from overflowing to the bonding area, thereby reducing the thickness of the solder mask 25 and decreasing the altitude of the chip 30 to achieve the effect of minimizing package size.

What is claimed is:

1. A chip package structure comprising:
a carrier board having a substrate provided with an upper surface and a concavity formed on the upper surface, a plurality of first conductive pads mounted on the upper surface of the substrate and arranged around the concavity of the substrate, and a solder mask applied to the substrate and provided with a plurality of openings respectively exposing portions of the first conductive pads;
a bonding adhesive applied to the concavity of the substrate;
a chip received in the concavity and attached to the carrier board through the bonding adhesive, the chip having a plurality of second conductive pads electrically connected to the first conductive pads of the carrier board through a plurality of wires; and
a package glue applied to the carrier board for covering the first conductive pads of the carrier board, the chip, and the wires.

2. The chip package structure as claimed in claim 1, wherein the concavity has an area larger than an area of the chip.

3. The chip package structure as claimed in claim 1, wherein the concavity has a depth greater than 0.1 mm.
